(19) United States
(12) Patent Application Publication
(10) Pub. No.: US 2026/0197208 A1
(43) Pub. Date: Jul. 9, 2026

(54) Power-Over Data Line Communication Device and Power-Over Data Line Communication System

(71) Applicant: Astemo, Ltd., Chiyoda-ku, Tokyo (JP)

(72) Inventor: Yutaka UEMATSU, Tokyo (JP)

(21) Appl. No.: 19/133,837

(22) PCT Filed: Aug. 10, 2023
(86) PCT No.: PCT/JP2023/029371

§ 371 Date: May 29, 2025

(30) Foreign Application Priority Data
Dec. 15, 2022 (JP) 2022-200479

(51) Int. Cl. H04L 25/02; H02J 1/06; H03H 7/09

(52) U.S. Cl. CPC H04L 25/0272; H02J 1/06; H03H 7/09

(57) ABSTRACT

A power-over data line communication device capable of suppressing an increase in mode conversion loss caused by variations in electrical characteristics is realized. A power-over data line communication device 1-1, in which power is overlaid on a differential signal wiring 8, includes a differential wiring 5-1 having signal wirings 6-1 and 7-1 connected to the differential signal wiring 8, a power supply element 30-1 that supplies a first applied voltage and a second applied voltage to the signal wirings 6-1 and 7-1, a high-frequency cut filter 11-1 connected to the wiring 6-1, a high-frequency cut filter 11-12 connected to the wiring 7-1, and an inductor 10-1 including coils 12-1 and 12-2, with the coil 12-1 being connected to the cut filter 11-1, the coil 12-2 being connected to the cut filter 11-2, and the coils 12-1 and 12-2 being magnetically coupled by reverse winding. An inductance value L1 of the cut filter 11-1 and an inductance value L3 of the coil 12-1 satisfy L1<1.5×L3, and an inductance value L2 of the cut filter 11-2 and an inductance value L4 of the coil 12-2 satisfy L2<1.5×L4.

### TECHNICAL FIELD

The present invention relates to a power-over data line communication device and a power-over data line communication system.

### BACKGROUND ART

In recent years, concerning signal transmission between devices mounted on vehicles, the speed of signal transmission has been increased using twisted pair cables. For example, in the in-vehicle Ethernet, standardization is progressing from 100BASE-T1, which has been the mainstream until now and transmits 100 Mbps, to 1000BASE-T1, which enables transmission of Gbps or more, or from multi-giga to 25 G BASE-T1.

Also in MIPI A-Phy, which is a communication standard for sensors, primarily cameras, standardization is in progress in such a manner that high-speed signals of Gbps or more are transmitted over twisted pair cables.

Furthermore, in these standards, in order to reduce the weight of harnesses, standardization of power-over data line (PoDL) technology for overlaying power on cables for signal transmission is also in progress.

The challenge with such an increase in speed of in-vehicle cable transmission is how to maintain EMC performance as the frequencies become higher. Since the current spectrum used for signal transmission exists at a high level up to a region exceeding the GHz band, it is necessary to suppress radiation in the high-frequency band.

At the same time, since the communication LSI has sensitivity to transmit and receive signals up to the GHz band, it is also necessary to suppress wraparound of noise in the GHz band.

The challenge with such an increase in speed of in-vehicle cable transmission is how to maintain EMC performance as the frequencies become higher. Since the current spectrum used for signal transmission exists at a high level up to a region exceeding the GHz band, it is necessary to suppress radiation in the high-frequency band. At the same time, since the communication LSI has sensitivity to transmit and receive signals up to the GHz band, it is also necessary to suppress wraparound of noise in the GHz band.

In the differential signal transmission that is the subject of the present invention, ideally, the transmission path on the positive (P) side and the transmission path on the negative (N) side constituting the differential transmission path are symmetrical, making it possible to cancel magnetic fields generated when reverse-phase currents flow through respective wirings, and to suppress radiation.

In addition, when common noise (common mode noise) is overlaid on both signal wirings, the noise can be canceled by a differential receiver, improving resistance to external noise.

However, in the P and N signal wirings constituting the differential transmission path, if the differential balance is disturbed due to variations in electrical characteristics caused by various factors, the benefits of this differential transmission cannot be used and EMC performance deteriorates. The degree of variation in the differential line is defined by a mode conversion loss, and is used as a criterion for determining EMC performance particularly in a high-frequency range of 10 MHz or more.

This represents an amount by which the differential mode is converted into the common mode or an amount by which the common mode is converted into the differential mode in the differential wiring. If this is large, radiation noise increases due to generation of unintended common mode components, noise resistance deteriorates due to conversion of common mode components into differential components.

As a prior art document related to the present invention, PTL 1 is known. PTL 1 discloses a system in which electronic devices are connected to each other by a twisted pair cable, and differential signals and power are overlaid on the twisted pair cable for transmission.

In this system, a DC cut-off capacitor is disposed on a signal line, and a filter element such as a common mode choke coil or an inductor is inserted as a PoDL filter on a power line.

As a result, the signal and the power are separated according to the frequency range of the filter element.

### CITATION LIST

### Patent Literature

PTL 1: U.S. Pat. No. 10,594,519 B2

### SUMMARY OF INVENTION

### Technical Problem

The technology of PTL 1 reduces leakage of common mode noise from a circuit on a wiring board to a twisted pair cable and suppresses propagation of common mode noise picked up by the twisted pair cable to the circuit on the wiring board by disposing a filter element between the communication circuit and the twisted pair cable.

However, there is a problem that, when an electrical characteristic imbalance occurs between P and N due to a power-over data line in PoDL filter components constituting the transmission system, a mode conversion loss increases in the transmission path, deteriorating EMC performance. In particular, there is a problem that, at low frequencies, variations in inductor components of the PoDL filter components occur due to differences in magnitude of the bias voltage, which contributes to an increase in mode conversion loss.

PTL 1 does not consider an increase in mode conversion loss.

Note that the mode conversion loss is expressed by a term of Scd of Mixed Mode S-Parameter.

An object of the present invention is to realize a power-over data line communication device and a power-over data line communication system capable of suppressing an increase in mode conversion loss caused by variations in electrical characteristics.

### Solution to Problem

In order to achieve the aforementioned object, the present invention is configured as follows.

A power-over data line communication device with power overlaid on a differential signal wiring includes: a first differential wiring having a first signal wiring and a second signal wiring connected to the differential signal wiring; a first power supply element configured to supply a first applied voltage and a second applied voltage to the first signal wiring and the second signal wiring, respectively; a first high-frequency cut filter connected to the first signal wiring on one end side thereof; a second high-frequency cut filter connected to the second signal wiring on one end side thereof; and a first inductor including a first coil and a second coil, with one end of the first coil being connected to the other end side of the first high-frequency cut filter, one end of the second coil being connected to the other end side of the second high-frequency cut filter, and the first coil and the second coil being magnetically coupled to each other by being reversely wound, in which an inductance value L1 of the first high-frequency cut filter and an inductance value L3 of the first coil of the first inductor have a relationship of L1<1.5×L3, and an inductance value L2 of the second high-frequency cut filter and an inductance value L4 of the second coil of the first inductor have a relationship of L2<1.5×L4.

### Advantageous Effects of Invention

According to the present invention, it is possible to realize a power-over data line communication device and a power-over data line communication system capable of suppressing an increase in mode conversion loss caused by variations in electrical characteristics.

Problems, configurations, and effects other than those described above will be apparent from the following description of embodiments for carrying out the invention.

### BRIEF DESCRIPTION OF DRAWINGS

FIG. 1 is a diagram illustrating a configuration of a power-over data line communication system according to a first embodiment of the present invention.

FIG. 2 is a diagram illustrating a first example of a circuit configuration of a PoDL filter in an example different from the present invention.

FIG. 3 is a diagram illustrating a second example of a circuit configuration of a PoDL filter in an example different from the present invention.

FIG. 4 is a diagram illustrating a configuration of a power-over data line communication device according to the first embodiment of the present invention.

FIG. 5 is a diagram illustrating an equivalent circuit of a four-terminal inductor component.

FIG. 6A is a diagram illustrating an effect of the present invention.

FIG. 6B is a diagram illustrating an effect of the present invention.

FIG. 7 is a diagram for explaining a problem to be solved by the present invention.

FIG. 8 is a diagram for explaining the grounds of numerical values handled in the present invention.

FIG. 9 is a diagram for explaining the grounds of numerical values handled in the present invention.

FIG. 10 is a diagram illustrating a circuit configuration according to a second embodiment of the present invention.

FIG. 11 is a diagram illustrating a layout pattern according to a third embodiment of the present invention.

FIG. 12 is a diagram illustrating a circuit configuration according to a fourth embodiment of the present invention.

FIG. 13 is a diagram illustrating a circuit configuration according to a fifth embodiment of the present invention.

FIG. 14 is a diagram illustrating a configuration of a power-over data line communication system according to a sixth embodiment of the present invention.

### DESCRIPTION OF EMBODIMENTS

Hereinafter, embodiments of the present invention will be described with reference to the drawings. The following description and drawings are examples for describing the present invention, and some omissions and simplifications have been made as appropriate for clarity of explanation. The present invention can be carried out in various other forms. Unless otherwise specified, each component may be singular or plural.

Positions, sizes, shapes, ranges, and the like of the components illustrated in the drawings may not represent actual positions, sizes, shapes, ranges, and the like in order to facilitate understanding of the invention. Therefore, the present invention is not necessarily limited to the positions, sizes, shapes, ranges, and the like disclosed in the drawings.

In a case where there are a plurality of components having the same or similar functions, they may be denoted by the same reference numerals with different subscripts in the description. However, when it is not necessary to distinguish the plurality of components from each other, the subscripts may be omitted in the description.

### EMBODIMENTS

### First Embodiment

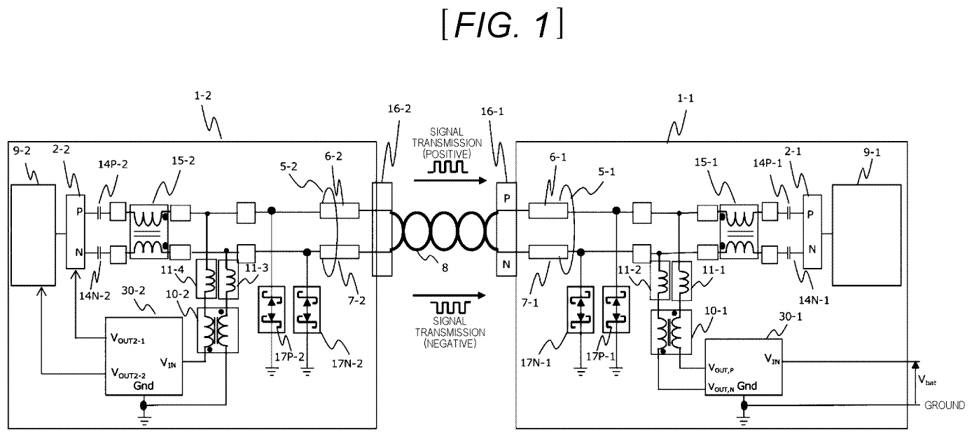

FIG. 1 is a diagram illustrating a configuration of a power-over data line communication system including power-over data line communication devices 1-1 (first power-over data line communication device) and 1-2 (second power-over data line communication device) according to the first embodiment of the present invention.

In FIG. 1, the power-over data line communication device 1-1, which is an electronic device, is connected to a twisted pair cable (differential signal wiring) 8 via a cable connector 16-1, and is connected to a power-over data line communication device 1-2, which is another external electronic device, to transmit a signal. At the same time, power is supplied from the power-over data line communication device 1-1 to the power-over data line communication device 1-2 by overlaying a power current on the twisted pair cable 8 in addition to the signal.

In the power-over data line communication device 1-1, a communication LSI 2-1 for performing communication and the cable connector 16-1 are connected to each other by a differential wiring 5-1 laid out on a printed circuit board. The differential wiring 5-1 includes a pair of a P-side signal wiring 6-1 (first signal wiring) and an N-side signal wiring 7-1 (second signal wiring).

Between the communication LSI 2-1 and the cable connector 16-1, there are arranged AC coupling capacitors 14P-1 and 14N-1 for cutting a DC potential, a common mode choke coil (CMCC) 15-1 for reducing common mode noise flowing into the communication LSI, and electrostatic protection elements 17P-1 and 17N-1 for avoiding electrostatic breakdown. In addition, there are arranged a power supply element (power supply IC) 30-1 (first power supply element) for overlaying power on the signal wiring, a power-over data line filter (PoDL filter) 10-1 (four-terminal differential mode inductor (first inductor)) for connecting a power line and a signal line, a first high-frequency cut filter 11-1 (two-terminal differential mode inductor (second inductor)), and a second high-frequency cut filter 11-2 (two-terminal differential mode inductor (second inductor)). A voltage Vbat is supplied to the power supply element 30-1 from an external power supply (not illustrated).

The power supply element 30-1 is configured to supply a first applied voltage Vout, P and a second applied voltage Vout, N to the first signal wiring 6-1 and the second signal wiring 7-1, respectively.

The four-terminal differential mode inductor 10-1 incorporates two coils that are wound in opposite directions and magnetically coupled to each other.

That is, one end side of one coil (first coil) of the four-terminal differential mode inductor 10-1 is connected to the other end side of the two-terminal differential mode inductor 11-1 which is the first high-frequency cut filter, and one end side of the other coil (second coil) of the four-terminal differential mode inductor 10-1 is connected to the other end side of the two-terminal differential mode inductor 11-2 which is the second high-frequency cut filter. The one coil and the other coil of the four-terminal differential mode inductor 10-1 are magnetically coupled to each other by being reversely wound.

The one coil of the four-terminal differential mode inductor 10-1 can be defined as a first inductor, and the other coil of the four-terminal differential mode inductor 10-1 can be defined as a second inductor.

The configuration of the PoDL filter will be described later in detail.

In addition, the communication LSI 2-1 is connected to an information processing LSI 9-1, and the information processing LSI 9-1 exchanges data with the communication LSI 2-1 to perform various types of processing. The power-over data line communication device 1-2 also has a circuit configuration similar to that of the power-over data line communication device 1-1.

That is, in the power-over data line communication device 1-2, there are arranged a cable connector 16-2, a P-side signal wiring 6-2 (third signal wiring), an N-side signal wiring 7-2 (fourth signal wiring), electrostatic protection elements 17N-2 and 17P-2, differential mode inductors 10-2 (four-terminal inductor (second inductor)), 11-3 (two-terminal inductor (third high-frequency cut filter)), and 11-4 (two-terminal inductor (fourth high-frequency cut filter)), and a common mode choke coil 15-2.

In addition, in the power-over data line communication device 1-2, there are arranged AC coupling capacitors 14P-2 and 14N-2, a communication LSI 2-2, an information processing LSI 9-2, and a power supply element 30-2 (second power supply element). The first applied voltage Vout, P and the second applied voltage Vout, N are supplied to the power supply element 30-2 via the signal wiring 6-2 (third signal wiring) and the signal wiring 7-2 (fourth signal wiring), respectively, and the power supply element 30-2 converts the supplied voltages into operating voltages.

However, a voltage is supplied from an external power supply to the power supply element 30-2 in the power-over data line communication device 1-2 unlike the power supply element 30-1 in the power-over data line communication device 1-1. The voltage supplied from the power-over data line communication device 1-1 and overlaid on the signal wiring is supplied to the power supply element 30-2 in the power-over data line communication device 1-2.

Note that this configuration is a general circuit configuration, and components (e.g., a common mode termination component, a filter component, a power-over data line filter component, etc.) other than those described herein may be added to the circuit configuration, and some of the components described herein may not be included in the circuit configuration.

There is a mode conversion loss as a representative value of EMC performance of the power-over data line communication devices 1-1 and 1-2. By checking whether an Scd11 value measured using a network analyzer from the cable connectors 16-1 and 16-2 is smaller than a target value, it is possible to determine whether the EMC performance is acceptable. Examples of such power-over data line communication devices 1-1 and 1-2 include an automatic driving electronic control unit (AD-ECU) for a automobile.

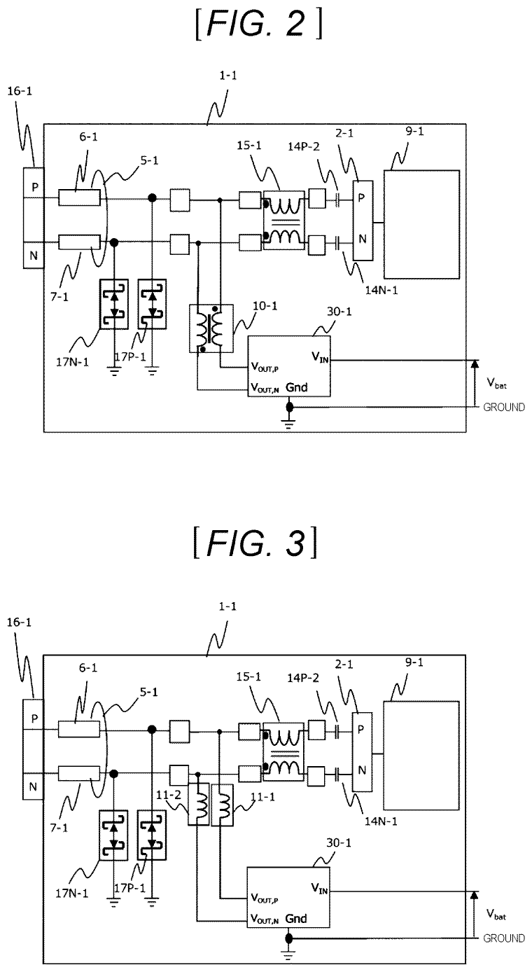

The feature of the components in the present invention is a circuit configuration of a PoDL filter which aims to keep this mode conversion loss low. Filter components different from those according to the present invention, including their differences in problem and effect, will be described with reference to FIGS. 2 to 6B.

FIG. 2 illustrates a first example (Comparative Example 1) of a circuit configuration of a PoDL filter in an example different from the present invention. In this example, the differential mode: inductor 10-1, which is a four-terminal inductor component, is utilized as a PoDL filter.

The differential mode inductor 10-1 has two coils wound in opposite directions and arranged closely in parallel to each other to magnetically strongly coupling the coils, thereby functioning to increase a differential impedance around a self-resonant frequency of the component and prevent inflow of a high-frequency differential current. As a result, a high-frequency differential signal passing through the P-side signal wiring 6-1, which is a differential transmission path, is prevented from leaking toward the power supply element 30-1.

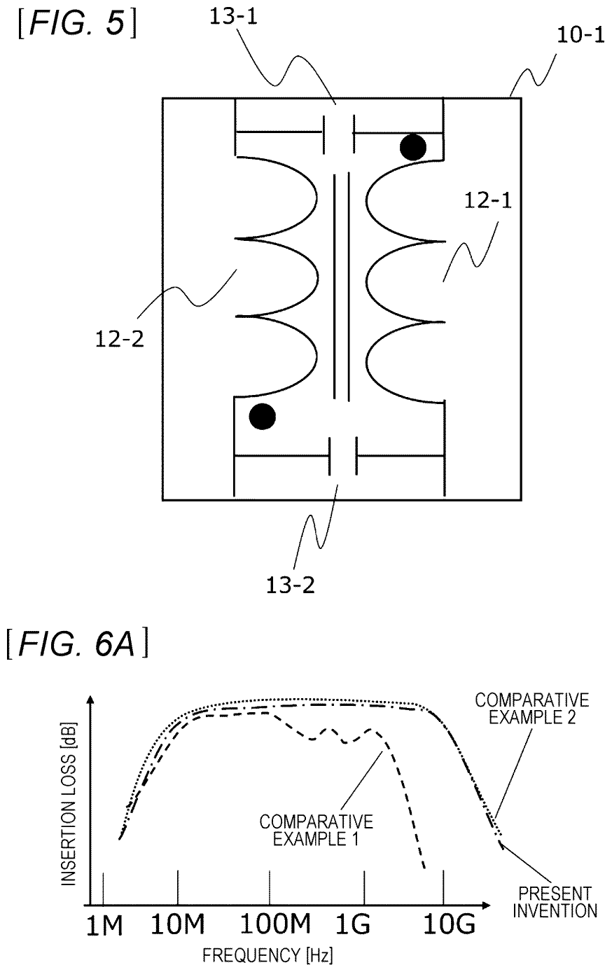

A simplified equivalent circuit of the four-terminal differential mode inductor 10-1 is shown in FIG. 5 (the four-terminal differential mode inductor 10-2 has a similar equivalent circuit).

In FIG. 5, the four-terminal differential mode inductor 10-1 includes a first coil 12-1 and a second coil 12-2, one end of the first coil 12-1 is connected to the other end side of the first high-frequency cut filter 11-1, one end of the second coil 12-2 is connected to the other end side of the second high-frequency cut filter 11-2, and the first coil 12-1 and the second coil 12-2 are magnetically coupled to each other by being reversely wound.

The two coils 12-1 (first coil) and 12-2 (second coil) wound in opposite directions have the same inductance value. In addition, these coils 12-1 and 12-2 need to be strongly coupled to each other, and are disposed close to each other in the same component, so that parasitic capacitances 13-1 and 13-2 exist between the coils.

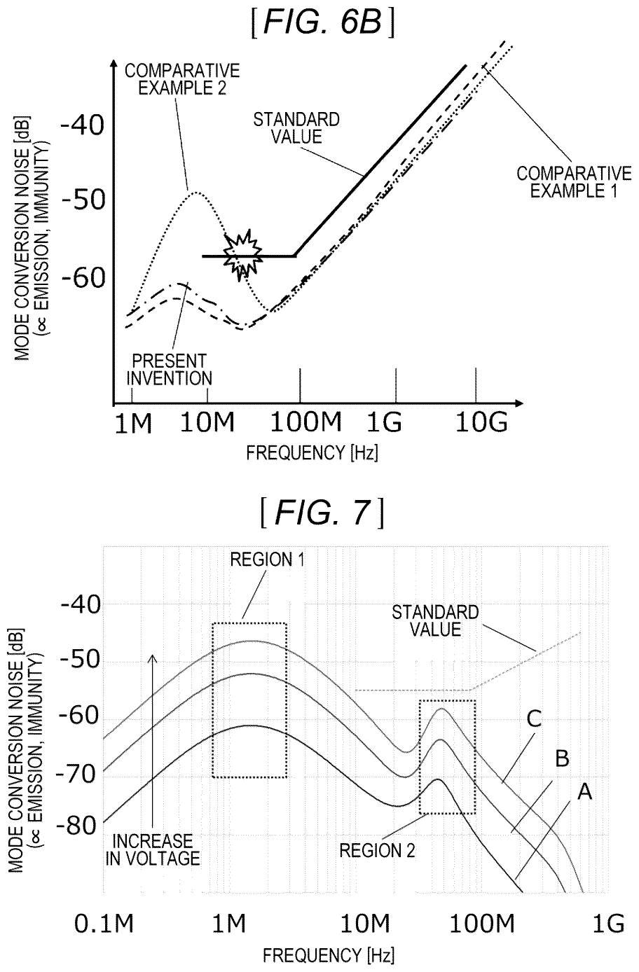

Problems of such a circuit configuration in terms of electrical characteristics will be described with reference to FIGS. 6A and 6B. FIG. 6A illustrates an insertion loss. In Comparative Example 1 different from the present invention and described with reference to FIG. 2, the insertion loss deteriorates above several hundred MHz, and therefore, there is a problem in achieving signal transmission performance at a level of several Gbps.

Next, FIG. 3 illustrates a second example (Comparative Example 2) of a circuit configuration of a PoDL filter different from that according to the present invention. In this example, the two-terminal inductor components 11-1 and 11-2 are utilized as a PoDL filter. The two-terminal inductor components 11-1 and 11-2 function to increase a differential impedance around a self-resonant frequency and prevent inflow of a high-frequency current.

As a result, a high-frequency P-side signal and a high-frequency N-side signal passing through the differential wiring 5-1 (first differential operation wiring) are prevented from leaking toward the power supply element 30-1. Problems of such a circuit configuration in terms of electrical characteristics will be described with reference to FIGS. 6A and 6B.

FIG. 6A illustrates characteristics of mode conversion noise. In Comparative Example 2 described with reference to FIG. 3, it can be seen that the mode conversion noise greatly increases below 100 MHz. This is because, in a state where a voltage is applied via the power supply element 30-1, a higher voltage (e.g., 12 V) is applied to the two-terminal inductor component 11-1 connected to the P-side wiring than the ground, while the same potential (0 V) is applied to the two-terminal inductor component 11-2 connected to the N-side wiring as the ground. As a result, the inductance of only the two-terminal inductor component 11-1 on the P-side decreases due to the application of the voltage, disrupting the balance between P and N inductance values, and this difference causes mode conversion loss.

In FIG. 6A, the standard value of Ethernet 1000BASE-T1 is shown for reference, but it can be seen that the specification deviates at several tens of MHz or less. On the other hand, from the viewpoint of insertion loss, since the independent two-terminal components are mounted on the P and N wirings, respectively, there is almost no adverse effect on the loss in the differential transmission line as illustrated in FIG. 6A.

Note that the problem of low-frequency mode conversion noise, which is a problem in the circuit configuration illustrated in FIG. 3, hardly appears in the circuit configuration of FIG. 2. This is because, in the four-terminal inductor, an effective inductance can be expressed by the sum of the effective inductance and the mutual inductance, and an effect of canceling the influence of the inductor on one side can be obtained.

In summary, in Comparative Example 1, the mode conversion noise can be kept low, but there is a problem in terms of insertion loss, making it difficult to cope with a high-frequency at a Gbps level. On the other hand, in Comparative Example 2, there is no problem in terms of insertion loss, but there is a problem that the mode conversion noise increases in a bias-applied state, making it difficult to achieve EMC performance.

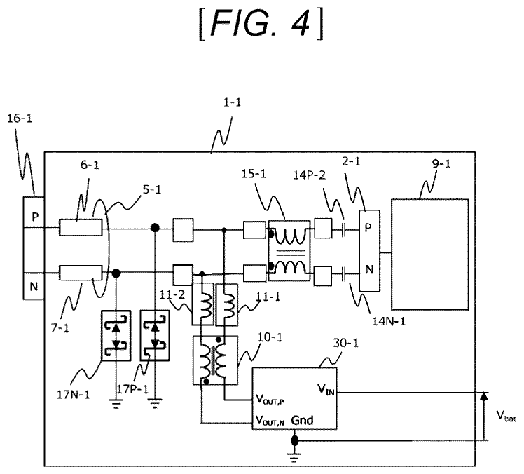

Therefore, in the present invention, as in the configuration illustrated in FIG. 4, the two-terminal differential mode inductors 11-1 and 11-2 are connected to the P-side signal wiring 6-1 and the N-side signal wiring 7-1, respectively, and are connected to the four-terminal differential mode inductor 10-1 on the opposite side, and then are connected to the power supply element 30-1.

In this configuration, the two-terminal differential mode inductors 11-1 and 11-2 connected to the signal wirings serve to cut off high-frequency components, effectively acting on high-speed signal transmission performance. On the other hand, the influence of the change in inductance balance between the two-terminal differential mode inductors 11-1 and 11-2 caused by the application of the voltage bias is reduced by connecting the four-terminal differential mode inductor 10-1, which is not easily affected by the bias voltage, to the two-terminal differential mode inductors 11-1 and 11-2 in series, to relatively reduce the influence of the two-terminal differential mode inductors 11-1 and 11-2, thereby suppressing mode conversion noise.

Although FIG. 4 illustrates the power-over data line communication device 1-1, similarly to the power-over data line communication device 1-1, the power-over data line communication device 1-2 also has a configuration in which the two-terminal differential mode inductors 11-1 and 11-2 are connected to the P-side signal wiring 6-1 and the N-side signal wiring 7-1, respectively, and are connected to the four-terminal differential mode inductor 10-1 on the opposite side, and then are connected to the power supply element 30-1.

FIG. 6A illustrates an insertion loss in a case where the circuit configuration according to the first embodiment is adopted, and FIG. 6B illustrates a characteristic of mode conversion noise according to the first embodiment. As illustrated in FIGS. 6A and 6B, both high-speed transmission and EMC performance can be achieved.

FIG. 7 illustrates a frequency characteristic of the mode conversion noise in a case where the circuit configuration of FIG. 4, which is the first embodiment of the present invention, is adopted.

As illustrated in FIG. 7, there are two frequency regions where the mode conversion noise has a maximum value, each of which is surrounded by a dotted line.

The first region is region 1 existing on the low frequency side, which is a component that increases the mode conversion noise by disrupting the balance between the inductance values of the two-terminal differential mode inductors 11-1 and 11-2 when a voltage is applied.

The second region is region 2 existing on the high-frequency side, which is a component resulting from impedance imbalance caused by the difference in the impedance peak between the P side and the N side due to LC anti-resonance generated by the inductance components of the two-terminal differential mode inductors 11-1 and 11-2 and the capacitance component of the four-terminal differential mode inductor 10-1.

As can be seen from FIG. 7, even in the circuit configuration according to the first embodiment, the mode conversion noise in region 1 may increase. This is because when the ratio between the inductance values of the two-terminal differential mode inductors 11-1 and 11-2 and the inductance values of the four-terminal differential mode inductor 10-1 constituting the PoDL filter is insufficient, the change in inductance of the two-terminal differential mode inductors 11-1 and 11-2 appears relatively large, and the benefit of the stability of the inductance values of the four-terminal differential mode inductor 10-1 cannot be obtained.

Here, a discussion will be given in a more quantitative sense. Considering the standard value of 1000BASE-T1, which is an in-vehicle Ethernet standard, as a reference, it has been analytically confirmed that when the difference in inductance value between P and N is less than 5%, a mode conversion noise amount with a margin with respect to the reference becomes a guide. However, this 5% criterion varies depending on the inductance value, and thus is merely a reference value.

That is, it is only required that the electrical characteristic values of the components be selected such that the changes in inductance value of the two-terminal differential mode inductors 11-1 and 11-2 on the P side caused by the bias are less than 5% with respect to the overall inductance value including the inductance of values the four-terminal differential mode inductor 10-1.

What is important to achieve this is a ratio between an inductance value (L1) of the two-terminal differential mode inductor 11-1, an inductance value (L2) of the two-terminal differential mode inductor 11-2, an inductance value (L3) of the first coil 12-1 of the four-terminal differential mode inductor 10-1, and an inductance value (L4) of the second coil 12-2 of the four-terminal differential mode inductor 10-1.

Since the four-terminal differential mode inductor 10-1 also has mutual inductance, it is difficult to obtain a precise numerical value in a mathematical manner. Therefore, a design space map capable of securing a margin with respect to a standard value of mode conversion noise by parametric analysis is obtained by simulation.

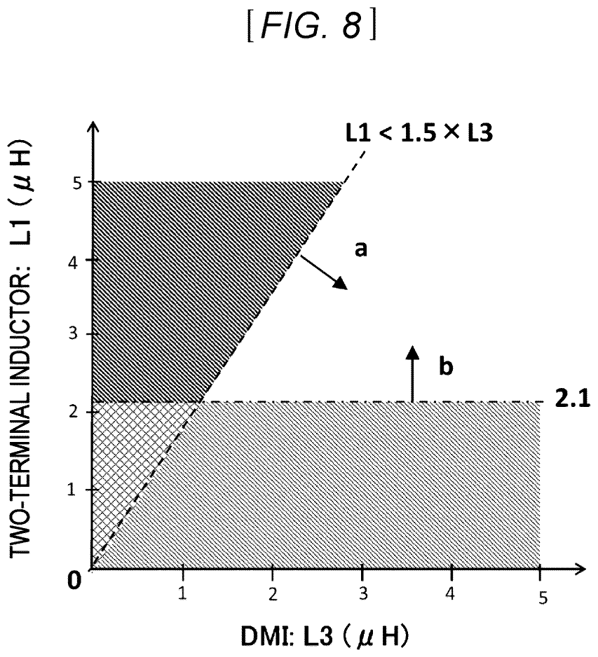

Experiments have shown that the amounts of variation caused by the bias voltage of the two-terminal differential mode inductors 11-1 and 11-2 were about 8% to 10% when 10 V was applied. For example, since a discussion has been made in the 1000BASE-T1 standard to apply a bias voltage of 12 V to 48 V, assuming that an 8% fluctuation occurs in L1 when 10 V is applied, a design space map as illustrated in FIG. 8 is obtained to see how the margin amount of the mode conversion noise changes depending on the combination of the numerical values of L1 (L2) and L3 (L4).

As a result, it has been confirmed that, in order to secure a margin in region 1 illustrated in FIG. 7, the inductance values L1 and L2 of the two-terminal differential mode inductors 11-1 and 11-2 are less than 1.5 times the inductance values L3 and L4 of the four-terminal differential mode inductor (DMI) 10-1, making it possible to secure a margin at various L values.

That is, conditional expressions for exhibiting the effect of the present invention are L1<1.5×L3 and L2<1.5×L4. It is a region ahead of arrow a from an inclined straight line indicated by a broken line in FIG. 8.

From the above considerations, the inductance value L1 of the two-terminal differential mode inductor 11-1, which is a first high-frequency cut filter, and the inductance value L3 on one side (the first inductor (the first coil 12-1)) of the four-terminal differential mode inductor 10-1 have a relationship of L1<1.5×L3, and the inductance value L2 of the two-terminal differential mode inductor 11-2, which is a second high-frequency cut filter, and the inductance value L4 on the other side (the second inductor (the second coil 12-2)) of 10-1 have a relationship of L2<1.5×L4.

As described above, in the first embodiment of the present invention, the power-over data line communication devices 1-1 and 1-2 have a configuration in which the two-terminal differential mode inductors 11-1 and 11-2 are connected to the P-side signal wiring 6-1 and the N-side signal wiring 7-1, respectively, and connected are to the four-terminal differential mode inductor 10-1 on the opposite side, and then are connected to the power supply element 30-1.

Therefore, it is possible to realize a power-over data line communication device and a power-over data line communication system capable of suppressing an increase in mode conversion loss caused by variations in electrical characteristics. That is, it is possible to realize a power-over data line communication device and a power-over data line communication system that improve EMC performance while achieving signal transmission performance at a Gbps level.

### Second Embodiment

Next, a second embodiment of the present invention will be described.

Since the overall configuration of the second embodiment is similar to that of the first embodiment, illustration of the overall configuration is omitted, and only the differences from the first embodiment will be described.

Constraint values of component parameters according to the second embodiment of the present invention will be described with reference to FIG. 8. As described above, it is preferable that the inductance values of the two-terminal differential mode inductors 11-1 and 11-2 are relatively smaller than the inductance values of the four-terminal differential mode inductor 10-1. However, when the value itself is small, an adverse side effect appears.

That is, it is the characteristic in the region 2 illustrated in FIG. 7. As described above, this characteristic is caused by resonance of parasitic components of the two-terminal differential mode inductors 11-1 and 1-2 and the four-terminal differential mode inductor 10-1. The maximum value of this characteristic results in large mode conversion noise, with the impedance peak characteristic difference that is sharper as the Q value of the resonance is higher.

That is, it is important to keep the Q value of the resonance at a certain value or less. In order to suppress the Q value of the parallel LC resonance, it is necessary to increase the L value. Assuming resonance with a parasitic capacitance of sub-pF to about 1 pF generally parasitic on the four-terminal differential mode inductor 10-1, it has been found that, when the analysis space is obtained as illustrated in FIG. 8, there is a margin with respect to the standard value when the inductance value of L1 is larger than 2.1 μH.

That is, in addition to the numerical limitations in the circuit configuration illustrated in FIG. 4 according to the first embodiment, the inductance values of the two-terminal differential mode inductors 11-1 and 11-2 are set to be larger than or equal to 2.1 μH in the second embodiment of the present invention. As illustrated in FIG. 8, the inductance values of the two-terminal differential mode inductors 11-1 and 11-2 are set in a region (L1<1.5×L3) from a broken line in a direction indicated by arrow a and in a region (L1≥2.1 μH) from an alternated long and short dash line in a direction indicated by arrow b.

The inductance values of the two-terminal differential mode inductors 11-3 and 11-4 of the power-over data line communication device 1-2 are also larger than or equal to 2.1 μH.

According to the second embodiment, it is possible to obtain an effect similar to that of the first embodiment, and it is also possible to further suppress mode conversion noise.

### Third Embodiment

Next, a third embodiment of the present invention will be described.

Since the overall configuration of the third embodiment is similar to that of the first embodiment, illustration of the overall configuration is omitted, and only the differences from the first embodiment will be described.

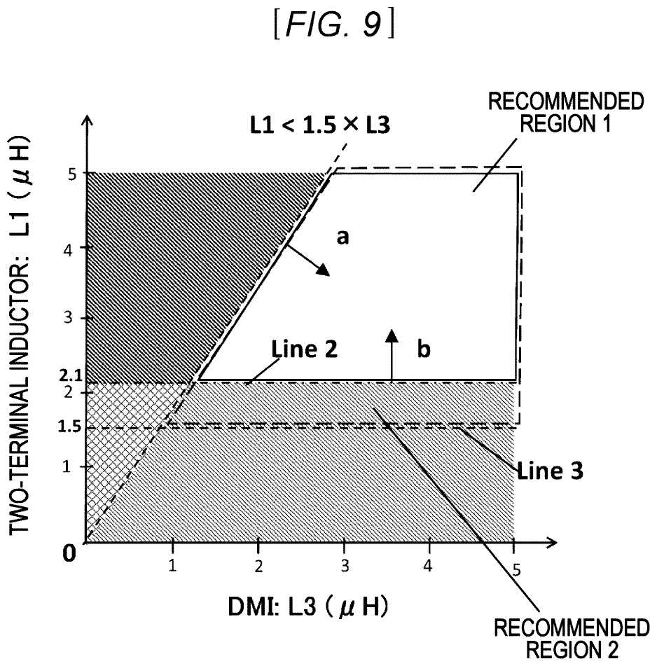

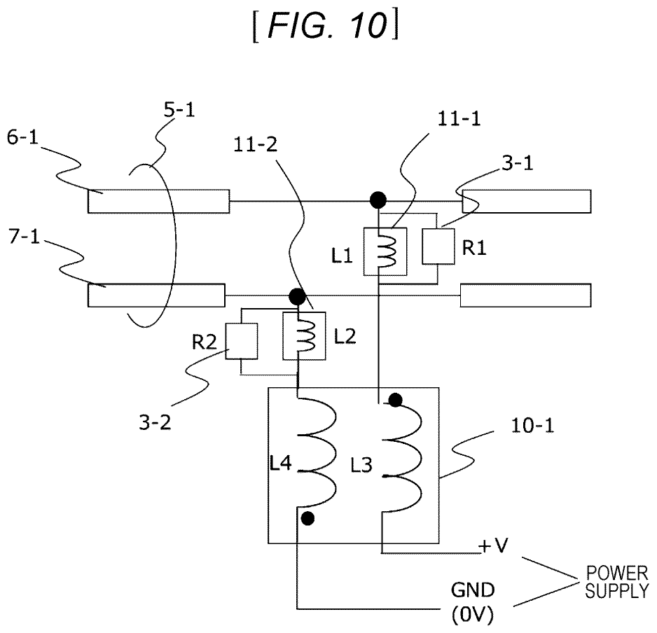

A circuit configuration and constraint values of component parameters according to the third embodiment of the present invention will be described with reference to FIGS. 9 and 10.

As described above, the characteristic of the region 2 illustrated in FIG. 7 is caused by the resonance of the parasitic components of the two-terminal differential mode inductors 11-1 and 11-2 and the four-terminal differential mode inductors 11-1 and 11-2, and the maximum value thereof depends on the Q value of the resonance. It is important to keep the Q value of the resonance at a certain value or less.

The condition for suppressing the Q value by increasing the L value by a certain value or more has been described above (Line 2 in FIG. 9). As another means for suppressing the Q value, a resistor may be inserted in parallel into the LC parallel resonant circuit.

Specifically, as illustrated in FIG. 10, resistance components 3-1 and 3-2 are connected in parallel to the two two-terminal differential mode inductors 11-1 and 11-2, respectively. At this time, the resistance components 3-1 and 3-2 have resistance values of between 500Ω and 1.5 kΩ. The lower limit of 500Ω is a value 10 times the characteristic impedance of the signal wiring, which is 50Ω, and is a minimum value necessary for suppressing leakage from the signal wiring.

In addition, the upper limit of 1.5 kΩ is a limit value that is a certain value to which the resistance value needs to decrease in order to lower the Q value.

FIG. 9 illustrates a change in boundary condition of the two-terminal differential mode inductors 11-1 and 11-2 when the parallel resistors 3-1 and 3-2 are inserted, in addition to the boundary lines in the first and second embodiments. By inserting the resistors in parallel, a Q value reduction effect is added by the resistors, and thus the constraint of the lower limit value for the inductors is lowered. Specifically, the boundary condition decreases to 1.5 μH.

That is, when resistance components of 500Ω to 1.5 kΩ are connected in parallel, the inductance values of the two-terminal differential mode inductors 11-1 and 11-2 should be larger than or equal to 1.5 μH.

FIG. 9 illustrates a result of analyzing mode conversion noise near the boundary condition for reference. It can be seen here that, when the obtained boundary condition is not satisfied, mode conversion noise slightly deviates from the standard value.

Note that, although FIG. 10 illustrates the configuration in the power-over data line communication device 1-1, resistors can also be connected in parallel to the two-terminal differential mode inductors 11-3 and 11-4 in the power-over data line communication device 1-2. In this case, the inductance values of the two-terminal differential mode inductors 11-3 and 11-4 should also be larger than or equal to 1.5 μH.

According to the third embodiment, it is possible to obtain effects similar to those of the first and second embodiments, and it is also possible to lower the constraint of the lower limit value for the two-terminal differential mode inductors 11-1 and 11-2 by inserting resistors parallel into the two-terminal differential mode inductors 11-1 and 11-2 so that the resistors add a Q value reduction effect.

### Fourth Embodiment

Next, a fourth embodiment of the present invention will be described.

Since the overall configuration of the fourth embodiment is similar to that of the first embodiment, illustration of the overall configuration is omitted, and only the differences from the first embodiment will be described.

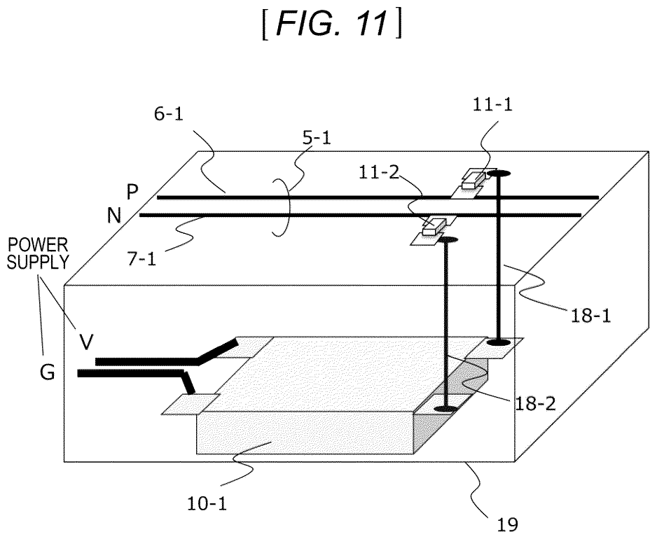

FIG. 11 is a diagram illustrating a mounting pattern according to the first embodiment of the present invention. As illustrated in FIG. 11, the P-side signal wiring 6-1 and the N-side signal wiring 7-1 constituting the differential wiring 5-1 are formed on a front surface (one surface) of a printed circuit board 19 in the power-over data line communication device 1-1. The two-terminal differential mode inductor components 11-1 and 11-2 are formed on both sides of the differential wiring 5-1, respectively, and are connected to the differential wiring 5-1.

In addition, the two-terminal differential mode inductor components 11-1 and 11-2 are connected to the four-terminal differential mode inductor 10-1 mounted on a back surface (the other surface) of the printed circuit board 19 via through holes 18-1 and 18-2. Power is supplied to the four-terminal differential mode inductor 10-1 by power supply lines G and V formed on the back surface of the printed circuit board 19.

With the configuration illustrated in FIG. 11, the distance between the P-side wiring 6-1 and the N-side wiring 7-1 can be kept constant, and the differential impedance formed by the two wiring lines, that is, the P-side signal wiring 6-1 and the N-side signal wiring line 7-1, can be kept uniform, making it possible to maintain good high-frequency electrical characteristics.

FIG. 11 illustrates an example of the power-over data line communication device 1-1, and the power-over data line device 1-2 has a similar configuration.

Note that, in a case where the four-terminal differential mode inductor 10-1 is disposed on the same layer (surface) as the two-terminal differential mode inductors 11-1 and 11-2, the P-side signal wiring 6-1 and the N-side signal wiring 7-1 need to be wired outside so as to make a large detour around the four-terminal differential mode inductor 10-1.

In this case, electromagnetic coupling between the P-side signal wiring 6-1 and the N-side signal wiring 7-1 changes, which causes impedance mismatch, In addition, there is a disadvantage in that noise resistance deteriorates due to a difference in noise mixed amount between the P-side signal wiring 6-1 and the N-side signal wiring 7-1.

Therefore, a deterioration in noise resistance can be prevented by taking measures such as arranging the two-terminal differential mode inductors 11-1 and 11-2 and the four-terminal differential mode inductor 10-1 separately on the front surface and the back surface of the printed board.

The fourth embodiment can have a configuration as illustrated in FIG. 11 after having a configuration similar to any of the first to third embodiments described above.

According to the fourth embodiment, it is possible to obtain effects similar to those of the first to third embodiments, and it is also possible to keep differential impedance formed by the P-side signal wiring 6-1 and the N-side signal wiring 7-1 uniform, thereby maintaining good high-frequency electrical characteristics.

### Fifth Embodiment

Next, a fifth embodiment of the present invention will be described.

Since the overall configuration of the fifth embodiment is similar to that of the first embodiment, illustration of the overall configuration is omitted, and only the differences from the first embodiment will be described.

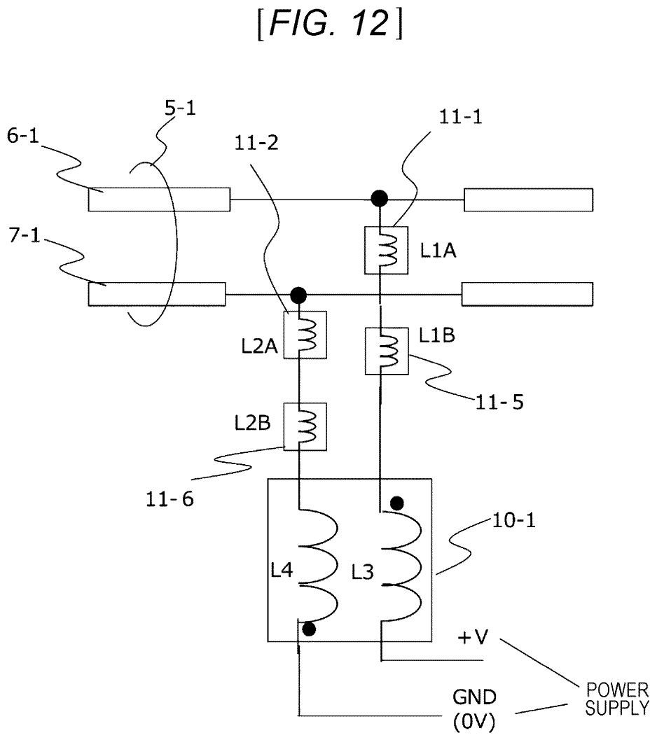

FIG. 12 is a diagram illustrating a circuit configuration according to the fifth embodiment of the present invention. The example illustrated in FIG. 12 is an example in which the two-terminal differential mode inductors 11-1 and 11-2 having the circuit configuration described in the first embodiment are configured with a larger number of inductors.

In the example illustrated in FIG. 12, the two two-terminal differential mode inductors 11-1 and 11-5 are connected in series to the P-side signal wiring 6-1, the two two-terminal differential mode inductors 11-2 and 11-6 are connected in series to the N-side signal wiring 7-1, and the four-terminal differential mode inductor 10-1 is disposed on the opposite side.

The advantage of dividing the inductors into two parts, the two-terminal differential mode inductors 11-1 and 11-5 and the two-terminal differential mode inductors 11-2 and 11-6, is that wideband filter performance can be obtained by using a plurality of inductor components having different self-resonance frequencies.

For example, rather than using one component having a self-resonance frequency of 700 MHz in the first embodiment, by dividing it into two components having self-resonance frequencies of 1 GHZ and 500 MHz, a filter having a high impedance in a wider frequency range can be configured.

In the present invention, the condition for the inductance value may be considered by replacing the condition for the inductance value of the two-terminal overlaid mode inductance component in the first to third embodiment with a total value of two two-terminal overlaid mode inductance components.

That is, L1 in the first embodiment and L1A+L1B in the fifth embodiment may be considered to be equivalent.

Note that FIG. 12 illustrates an example of the power-over data line communication device 1-1, and the power-over data line device 1-2 has a similar configuration.

According to the fifth embodiment, it is possible to obtain effects similar to those of the first to fourth embodiments, and it is also possible to obtain wideband filter performance.

### Sixth Embodiment

Next, a sixth embodiment of the present invention will be described.

Since the overall configuration of the sixth embodiment is similar to that of the first embodiment, illustration of the overall configuration is omitted, and only the differences from the first embodiment will be described.

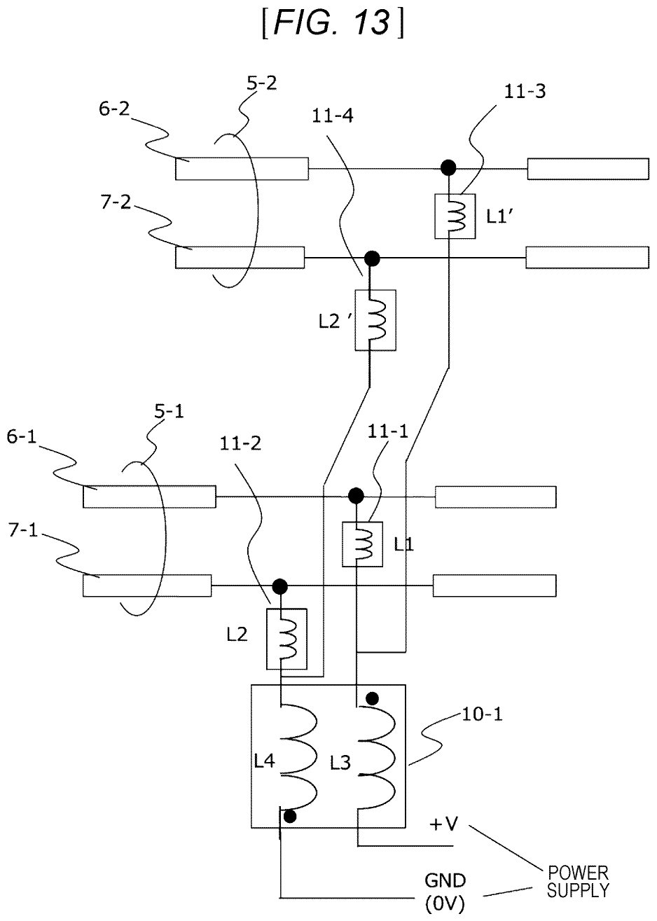

FIG. 13 is a diagram illustrating a circuit configuration according to the sixth embodiment of the present invention. The sixth embodiment is an embodiment where power is supplied from a common power supply element in a case where there are two pairs of differential wirings.

As illustrated in FIG. 13, there are a differential wiring 5-1 and a differential wiring 5-2 (second differential wiring) (the differential wiring 5-1 in the power-over data line communication device 1-1 and the differential wiring 5-2 in the power-over data line communication device 1-2 illustrated in FIG. 1), while the two-terminal differential mode inductors 11-1 and 11-2 are connected to the differential wiring 5-1, and the two-terminal differential mode inductors 11-3 and 11-4 are connected to the differential wiring 5-2. Further, one four-terminal differential mode inductor 10-1 is connected to the two-terminal differential mode inductors 11-1, 11-2, 11-3, and 11-4, with the two-terminal differential mode inductors 11-1 and 11-3, which are P-side components, being connected to the power supply side of the four-terminal differential mode inductor 10-1, and the two-terminal differential mode inductors 11-2 and 11-4, which are N-side components, being connected to the ground side of the four-terminal differential mode inductor 10-1.

That is, the four-terminal differential mode inductor 10-1 operates as a four-terminal differential mode inductor 10-1 and also operates as a four-terminal differential mode inductor 10-2.

With such a configuration, by sharing the four-terminal differential mode inductor 10-1 which is a large component, it is possible to reduce the number of components and reduce the cost.

Even with such a configuration, since the two-terminal differential mode inductors 11-1, 11-2, 11-3, and 11-4 are disposed at points where high-frequency portions are connected, the high-frequency characteristics do not deteriorate, and it is possible to guarantee the change in balance between the inductance values of the two-terminal differential mode inductors 11-1, 11-2, 11-3, and 11-4 by the ratio of their inductance values to the inductance value of the four-terminal differential mode inductor 10-1.

According to the sixth embodiment, it is possible to obtain an effect similar to that of the first embodiment, and it is also possible to reduce the number of components and reduce the cost by sharing the four-terminal differential mode inductor 10-1, which is a large component.

### Seventh Embodiment

Next, a seventh embodiment of the present invention will be described.

Since the overall circuit configuration of the seventh embodiment is similar to that of the first embodiment, illustration of the overall circuit configuration is omitted, and only the differences from the first embodiment will be described.

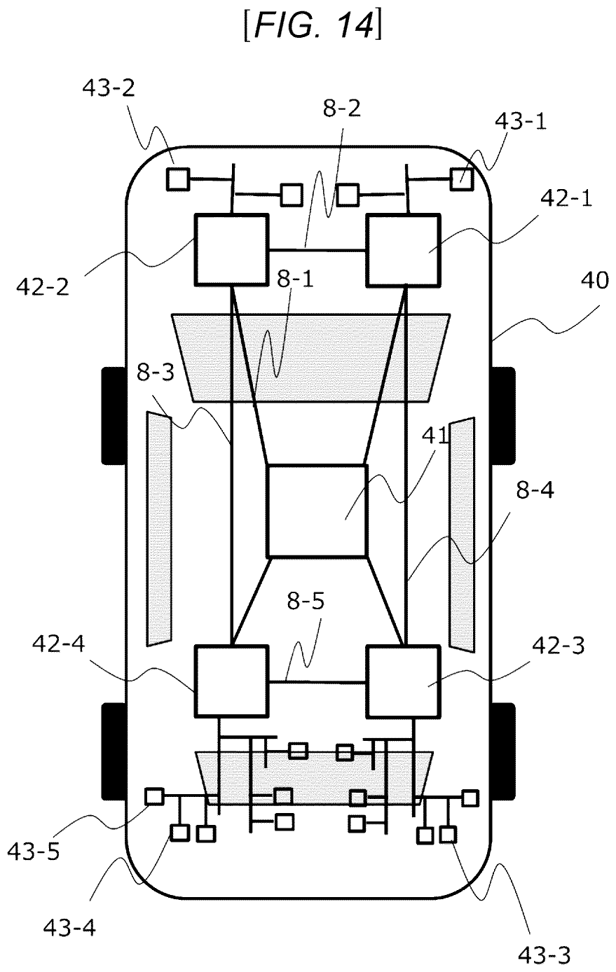

FIG. 14 is a diagram illustrating an example of application according to the seventh embodiment of the present invention. In the seventh embodiment, an example of use in a zone architecture that is expected to be used as a future in-vehicle architecture. In the zone architecture, a zone ECU 41-1, a zone ECU 42-2, a zone ECU 42-3, and a zone ECU 42-4 are connected to each other by a cable 8-1, a cable 8-2, a cable 8-3, a cable 8-4, a cable 8-5, or the like in respective zones determined by physical positions with a central ECU 41-1 of an automobile vehicle 40 as the center, and the zone ECU 42-1, the zone ECU 42-2, the zone ECU 42-3, and the zone ECU 42-4 are further connected to an ECU 43-1, an ECU 43-2, an ECU 43-3, an ECU 43-4, an ECU 43-5, and the like in the respective zones.

It is assumed that the zone ECU 42-1, the zone ECU 42-2, the zone ECU 42-3, and the zone ECU 42-4 have a configuration in which power supply lines are redundant between the zone ECUs for power supply, and power-over data lines are provided by the cables connecting the zone ECUs to each other.

The power-over data line communication device 1-1 or 1-2 according to any of the first to sixth embodiments described above can be applied to the zone ECU 42-1, the zone ECU 42-2, the zone ECU 42-3, and the zone ECU 42-4.

In this case, it is assumed that a high voltage is used to supply power to a zone ECU having relatively large power consumption. Therefore, it is essential to use the PoDL filter circuit configuration according to the present invention in order to avoid a deterioration in EMC performance caused by applying a high bias, and the seventh embodiment is considered to be effective.

According to the seventh embodiment, it is possible to realize a vehicle-mounted power-over data line communication system having the effects of the first to sixth embodiments.

Note that, although the present invention is described in the present specification on the premise that it is applied to an in-vehicle device, the present invention can also be applied to other applications using similar communication systems. For example, a similar effect can be exhibited in communication between an industrial robot and an electronic camera.

The embodiments and modifications described above are merely exemplary, and the present invention is not limited thereto as long as the features of the invention are not impaired.

Although the various embodiments and modifications have been described above, the present invention is not limited thereto.

Other aspects conceivable within the technical spirit of the present invention also fall within the scope of the present invention.

### REFERENCE SIGNS LIST

1-1, 1-2 power-over data line communication device (electronic device)
2-1, 2-2 communication LSI
3-1, 3-2 resistance component
5-1, 5-2 differential wiring
6-1, 6-2 P-side signal wiring
7-1, 7-2 N-side signal wiring
8, 8-1, 8-2, 8-3, 8-4 twisted pair cable (differential signal wiring)
9-1, 9-2 information processing LSI
10-1, 10-2 four-terminal differential mode inductor
11-1, 11-2, 11-3, 11-4, 11-5, 11-6 two-terminal differential mode inductor
12-1, 12-2 coil inside differential mode inductor (first coil, second coil)
13-1, 13-2 parasitic capacitance between coils of differential mode inductor
14N-1, 14N-2, 14P-1, 14N-2 AC coupling capacitor
15-1, 15-2 common mode choke coil (CMCC)
16-1, 16-2 cable connector
17N-1, 17-2, 17P-1, 17P-2 electrostatic protection element
18-1, 18-2 through hole
19 printed circuit board
30-1, 30-2 power supply element (power supply IC)
40 automobile vehicle
41 central ECU
42-1, 42-2, 42-3, 42-4 Zone ECU
43-1, 43-2, 43-3, 43-4 ECU

1. A power-over data line communication device with power overlaid on a differential signal wiring, the power-over data line communication device comprising:
a first differential wiring having a first signal wiring and a second signal wiring connected to the differential signal wiring;
a first power supply element configured to supply a first applied voltage and a second applied voltage to the first signal wiring and the second signal wiring, respectively;
a first high-frequency cut filter connected to the first signal wiring on one end side thereof;
a second high-frequency cut filter connected to the second signal wiring on one end side thereof; and
a first inductor including a first coil and a second coil, with one end of the first coil being connected to the other end side of the first high-frequency cut filter, one end of the second coil being connected to the other end side of the second high-frequency cut filter, and the first coil and the second coil being magnetically coupled to each other by being reversely wound,
wherein an inductance value L1 of the first high-frequency cut filter and an inductance value L3 of the first coil of the first inductor have a relationship of L1<1.5×L3, and
an inductance value L2 of the second high-frequency cut filter and an inductance value L4 of the second coil of the first inductor have a relationship of L2<1.5×L4.

2. A power-over data line communication system, comprising:
a first power-over data line communication device constituted by the power-over data line communication device according to claim 1; and a second power-over data line communication device,
wherein the second power-over data line communication device includes:
a second differential wiring having a third signal wiring and a fourth signal wiring connected to the differential signal wiring;
a second power supply element to which the first applied voltage and the second applied voltage are supplied via the third signal wiring and the fourth signal wiring, respectively, and are converted into an operating voltage;
a third high-frequency cut filter connected to the third signal wiring on one end side thereof;
a fourth high-frequency cut filter connected to the fourth signal wiring on one end side thereof; and
a second inductor including a third coil and a fourth coil, with one end of the third coil being connected to the other end side of the third high-frequency cut filter, one end of the second coil being connected to the other end side of the fourth high-frequency cut filter, and the third coil and the fourth coil being magnetically coupled to each other by being reversely wound,
an inductance value L5 of the third high-frequency cut filter and an inductance value L7 of the third coil of the second inductor have a relationship of L5<1.5×L7,
an inductance value L6 of the fourth high-frequency cut filter and an inductance value L8 of the fourth coil of the second inductor have a relationship of L6<1.5×L8, and
the first power-over data line communication device and the second power-over data line communication device are connected to each other via the differential signal wiring.

3. The power-over data line communication system according to claim 2,
wherein power is supplied from the first power-over data line communication device to the second power-over data line communication device via the differential signal wiring.

4. The power-over data line communication system according to claim 2, wherein the inductance value L1 of the first high-frequency cut filter, the inductance value L2 of the second high-frequency cut filter, the inductance value L5 of the third high-frequency cut filter, and the inductance value L6 of the fourth high-frequency cut filter are larger than or equal to 2.1 μH.

5. The power-over data line communication device according to claim 1, further comprising:
a first resistor disposed in parallel with the first high-frequency cut filter; and
a second resistor disposed in parallel with the second high-frequency cut filter,
wherein a resistance value r1 of the first resistor is 500Ω≤r1≤1500 Ω,
a resistance value r2 of the second resistor is 500Ω≤r2≤1500Ω, and
the inductance value L1 of the first high-frequency cut filter is larger than or equal to 1.5 μH, and the inductance value L2 of the second high-frequency cut filter is larger than or equal to 1.5 μH.

6. The power-over data line communication system according to claim 2, further comprising:
a third resistor disposed in parallel with the third high-frequency cut filter; and
a fourth resistor disposed in parallel with the fourth high-frequency cut filter,
wherein a resistance value r3 of the third resistor is 500Ω≤r3≤1500Ω,
a resistance value r4 of the fourth resistor is 500Ω≤r4≤1500Ω, and
the inductance value L5 of the third high-frequency cut filter is larger than or equal to 1.5 μH, and the inductance value L6 of the fourth high-frequency cut filter is larger than or equal to 1.5 μH.

7. The power-over data line communication device according to claim 1, wherein
the first high-frequency cut filter and the second high-frequency cut filter are two-terminal differential mode inductors,
the first inductor is a four-terminal differential mode inductor,
the first high-frequency cut filter and the second high-frequency cut filter are formed on one surface of a substrate on which the first signal wiring and the second signal wiring are formed, and
the first inductor is formed on the other surface of the substrate.

8. The power-over data line communication system according to claim 2, wherein
the third high-frequency cut filter and the fourth high-frequency cut filter are two-terminal differential mode inductors,
the second inductor is a four-terminal differential mode inductor,
the third high-frequency cut filter and the fourth high-frequency cut filter are formed on one surface of a substrate on which the third signal wiring and the fourth signal wiring are formed, and
the second inductor is formed on the other surface of the substrate.

9. The power-over data line communication device according to claim 1, wherein
the first high-frequency cut filter is a plurality of two-terminal differential mode inductors connected in series to each other, and
the second high-frequency cut filter is a plurality of two-terminal differential mode inductors connected in series to each other.

10. The power-over data line communication system according to claim 2, wherein
the other end side of the third high-frequency cut filter is connected to one end of the first coil of the first inductor of the first power-over data line communication device,
the other end side of the fourth high-frequency cut filter is connected to one end of the second coil of the first inductor of the first power-over data line communication device, and
the first inductor of the first power-over data line communication device operates as the first inductor and also operates as the second inductor of the second power-over data line communication device.

11. The power-over data line communication system according to claim 2, wherein a network including at least one first power-over data line communication device and at least two second power-over data line communication devices connected to the first power-over data line communication device via the differential signal wiring is formed.
